(19) United States
(12) Patent Application Publication
(10) Pub. No.: US 2026/0238119 A1
(43) Pub. Date: Aug. 13, 2026

(54) SYSTEM WITH ZERO OVERVOLTAGE SWITCHING

(71) Applicant: SEMICONDUCTOR COMPONENTS INDUSTRIES, LLC, Scottsdale, AZ (US)

(72) Inventor: Daniel Leon GOLDMANN, Munich (DE)

(73) Assignee: SEMICONDUCTOR COMPONENTS INDUSTRIES, LLC, Scottsdale, AZ (US)

(21) Appl. No.: 19/462,476

(22) Filed: Jan. 28, 2026

Related U.S. Application Data
(60) Provisional application No. 63/755,895, filed on Feb. 7, 2025.

(51) Int. Cl. H02M 1/32; H02M 1/00; H02M 7/537

(52) U.S. Cl. CPC H02M 1/32; H02M 1/0054; H02M 7/537

(57) ABSTRACT

A switch system includes (i) high-side and low-side transistors coupled in series between a DC voltage bus and a system ground, (ii) a switch-node capacitance including high-side and low-side capacitances from respective drains to sources of the high-side and low-side transistors, (iii) a DC power source coupled between the DC voltage bus and the system ground, wherein the DC power source, the high-side transistor, and the low-side transistor form a loop with a parasitic loop inductance, (iv) a control circuit configured to drive the high-side transistor and the low-side transistor on and off in an alternating fashion from each other, (v) an auxiliary circuit configured to, during a switching transition of the low-side transistor from a low-side on-state to a low-side off-state, provide an offset current to the low-side transistor that, in combination with a load current, triggers a resonance of the parasitic loop inductance and the switch-node capacitance.

### PRIORITY

This application claims the benefit of provisional patent application No. 63/755,895, filed Feb. 7, 2025, which is hereby incorporated by reference herein in its entirety.

### TECHNICAL FIELD

The disclosure relates generally to integrated circuit technology, and particularly to switching circuits.

### BACKGROUND

Power electronics may be used to control the conversion and distribution of electric power. For example, switching power converters may be used to create a direct current (“DC”) voltage from an alternating current (“AC”) voltage by switching current through a magnetic element such as an inductor. Conversely, inverters may be used to convert a DC voltage to an AC voltage. In these and other forms of power electronics, power switches may be used to control the conversion and flow of power through the power-conversion system and to the electronic circuitry to be powered by the device.

The power switches in power conversion systems may be required to switch at high frequencies, drive high currents, and withstand large voltages. The inventor of embodiments of the present disclosure have recognized that such power switches may suffer from unstable oscillations and drain-voltage overshoots due to inductive loads and the turn-off characteristics of the power switch. The inventor of embodiments of the present disclosure have also recognized that such drain-voltage overshoots may damage the power switch unless otherwise constricted. Currently available techniques for constricting such overshoots come at the expense of additional components that increase system costs. For example, the use of an additional R-C snubber across the drain to source of the power switch may consume additional space and increase costs. Other techniques, using for example an auxiliary resonant commutated pole (ARCP) topology may provide soft-switching, but may require additional components including high-current transistors that increase system costs. Embodiments of the present disclosure may address one or more of these challenges.

### SUMMARY

The examples herein enable a switch system implemented to reduce or elimination oscillations and/or drain-voltage overshoots while also improving system-level efficiency.

According to one example, a switch system includes (i) a high-side transistor coupled between a DC voltage bus and a switching node, (ii) a low-side transistor coupled between the switching node and a system ground, (iii) a switch-node capacitance including a high-side capacitance from a drain to a source of the high-side transistor and a low-side capacitance from a drain to a source of the low-side transistor, (iv) a DC power source coupled between the DC voltage bus and the system ground, wherein the DC power source, the high-side transistor, and the low-side transistor form a loop with a parasitic loop inductance, (v) a control circuit configured to drive the high-side transistor and the low-side transistor on and off in an alternating fashion from each other, and (vi) an auxiliary circuit configured to, during a switching transition of the low-side transistor from a low-side on-state to a low-side off-state, provide an offset current to the low-side transistor that, in combination with a load current, triggers a resonance of the parasitic loop inductance and the switch-node capacitance. In some embodiments, the offset current is a non-zero current that forces a switch current through the low-side transistor during the switching transition of the low-side transistor to trigger an n-half resonant transition wherein n is a positive odd whole number. In the same or different embodiments, n is one of 3 or 5 or more. In the same or different embodiments, the offset current is a non-zero current that forces a switch current through the low-side transistor during the switching transition of the low-side transistor to approximately equal:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents the high-side capacitance, C_{DSLS} represents the low-side capacitance, L_{PAR} represents the parasitic loop inductance, VBUS represents a voltage of the DC voltage bus relative to the system ground, and n is a positive odd whole number. In the same or different embodiments, the high-side capacitance includes a parasitic drain-to-source capacitance of the high-side transistor, and the low-side capacitance includes a parasitic drain-to-source capacitance of the low-side transistor. In the same or different embodiments, the high-side capacitance further includes a first discrete capacitor, and the low-side capacitance further includes a second discrete capacitor. In the same or different embodiments, the control circuit is configured to monitor a switch current through the low-side transistor prior to the switching transition, and to drive the auxiliary circuit to provide the offset current based on the switch current. In the same or different embodiments, the control circuit includes a low-side driver configured to transition the low-side transistor from an on-state to an off-state in less than one resonant period of the parasitic loop inductance and the switch-node capacitance. In the same or different embodiments, the control circuit includes a low-side driver including a drive circuit having a first output and a second output, a gate resistance coupled between the first output of the drive circuit and a gate of the low-side transistor, and a pull-down transistor having a gate driven by the second output of the drive circuit, a drain coupled to the gate of the low-side transistor, and a source coupled to a source of the low-side transistor. In the same or different embodiments, the high-side transistor and the low-side transistor are silicon carbide transistors. In the same or different embodiments, the high-side transistor and the low-side transistor are NMOS transistors.

According to another example, a switch system includes (i) a high-side transistor coupled between a DC voltage bus and a switching node, (ii) a low-side transistor coupled between the switching node and a system ground, (iii) a switch-node capacitance including a high-side capacitance from a drain to a source of the high-side transistor and a low-side capacitance from a drain to a source of the low-side transistor, (iv) a DC power source coupled between the DC voltage bus and the system ground, wherein the DC power source, the high-side transistor, and the low-side transistor form a loop with a parasitic loop inductance, (v) a control circuit configured to drive the high-side transistor and the low-side transistor on and off in an alternating fashion from each other, and (vi) an auxiliary circuit configured to, during a switching transition of the low-side transistor from a low-side on-state to a low-side off-state, provide an offset current to the low-side transistor that, in combination with a load current, triggers a resonant transition based on a resonance of the parasitic loop inductance and the switch-node capacitance. In some embodiments, the offset current is a non-zero current that forces the switch current through the low-side transistor during the switching transition of the low-side transistor to approximately equal:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents the high-side capacitance, C_{DSLS} represents the low-side capacitance, L_{PAR} represents the parasitic loop inductance, VBUS represents a voltage of the DC voltage bus relative to the system ground, and n is a positive odd whole number. In the same or different embodiments, monitor a switch current through the low-side transistor prior to the switching transition, and drive the auxiliary circuit to provide the offset current based on the switch current.

Another example provides a method for operating a switch system, wherein the method includes driving a high-side transistor in a high-side off-state, the high-side transistor is coupled between a switching node and a DC voltage bus powered by a DC power supply, driving a low-side transistor in a low-side on-state, the low-side transistor coupled between the switching node and a system ground, providing an offset current that, in addition to a load current, increases a switch current through the low-side transistor toward a target value for trigging a resonant transition, and transitioning the low-side transistor from the low-side on-state to a low-side off-state when, based in part on the offset current, the switch current reaches the target value to trigger the resonant transition based on a resonance of a parasitic loop inductance of a loop formed by the DC power supply, the high-side transistor, and the low-side transistor, and a switch-node capacitance including a high-side capacitance from a drain to a source of the high-side transistor and a low-side capacitance from a drain to a source of the low-side transistor. In some embodiments, the resonant transition is an n-half resonant transition wherein n is a positive odd whole number. In the same or different embodiments, the offset current is a non-zero current that forces the switch current through the low-side transistor during an on-to-off transition of the low-side transistor to approximately equal:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents a high-side capacitance from a drain to source of the high-side transistor, C_{DSLS} represents a low-side capacitance from a drain to a source of the low-side transistor, L_{PAR} represents the parasitic loop inductance, VBUS represents a voltage of the DC voltage bus relative to the system ground, and n is a positive odd whole number. In the same or different embodiments, the method further comprises monitoring the switch current through the low-side transistor, and generating the offset current based on a value of the switch current relative to the target value. In the same or different embodiments, the switch-node capacitance includes a parasitic drain-to-source capacitance of the high-side transistor and a parasitic drain-to-source capacitance of the low-side transistor. In the same or different embodiments, the switch-node capacitance further includes a first discrete capacitor coupled from a drain to a source of the high-side transistor and a second discrete capacitor coupled from a drain to a source of the low-side transistor.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a schematic diagram of a switch system.

FIG. 2A illustrates plot diagrams of the drain voltage of a low-side transistor in response to a switching transition.

FIG. 2B illustrates a plot diagram of the maximum voltage incurred at the drain of a low-side transistor during the switching transition as a function of switch current.

FIG. 3 illustrates a schematic diagram of a switch system in accordance with embodiments of the present disclosure.

FIG. 4 illustrates a plot diagram of the maximum voltage incurred at the drain of a low-side transistor during the switching transition as a function of switch current in accordance with embodiments of the present disclosure.

FIG. 5 illustrates plot diagrams of waveforms within a switch system in accordance with embodiments of the present disclosure.

FIG. 6 illustrates a schematic diagram of a low-side driver in accordance with embodiments of the present disclosure.

FIG. 7 illustrates a schematic diagram of a switch system in accordance with embodiments of the present disclosure.

FIG. 8 illustrates an example method of operating a switch system in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections. As used herein, the term “and/or” includes any and all combinations of one or more of the associated listed items.

Further, although the terms “first,” “second,” and so forth may be used herein to describe various elements, these elements should not be limited by these terms. Terms such as “first” and “second” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element.

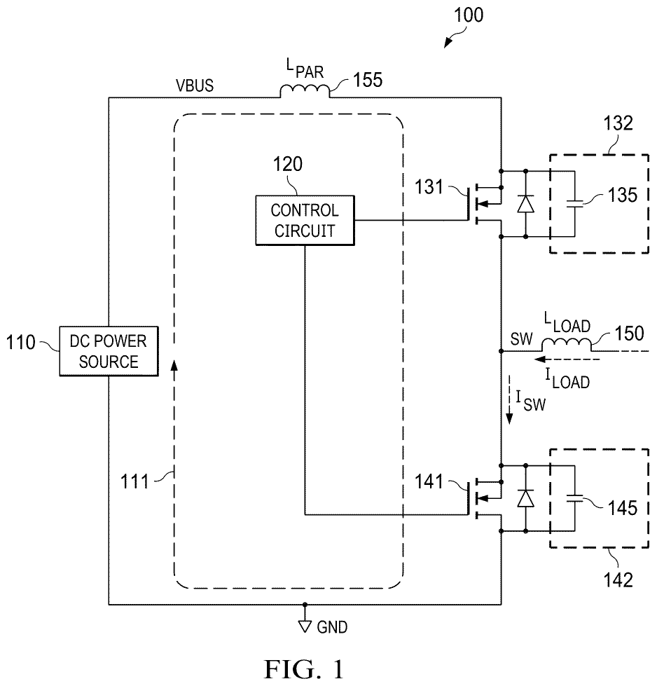

FIG. 1 illustrates a schematic diagram of switch system 100. In some embodiments, switch system 100 may include DC power source 110, control circuit 120, high-side transistor 131, low-side transistor 141, and load 150.

DC power source 110 may be coupled between a DC voltage bus VBUS and a system ground GND. DC power source 110 may provide the power that is ultimately provided to load 150 via high-side transistor 131 and low-side transistor 141. In some embodiments, DC power source 110 may be a high-voltage battery configured to operate, for example, at 400 V, 800 V, or more.

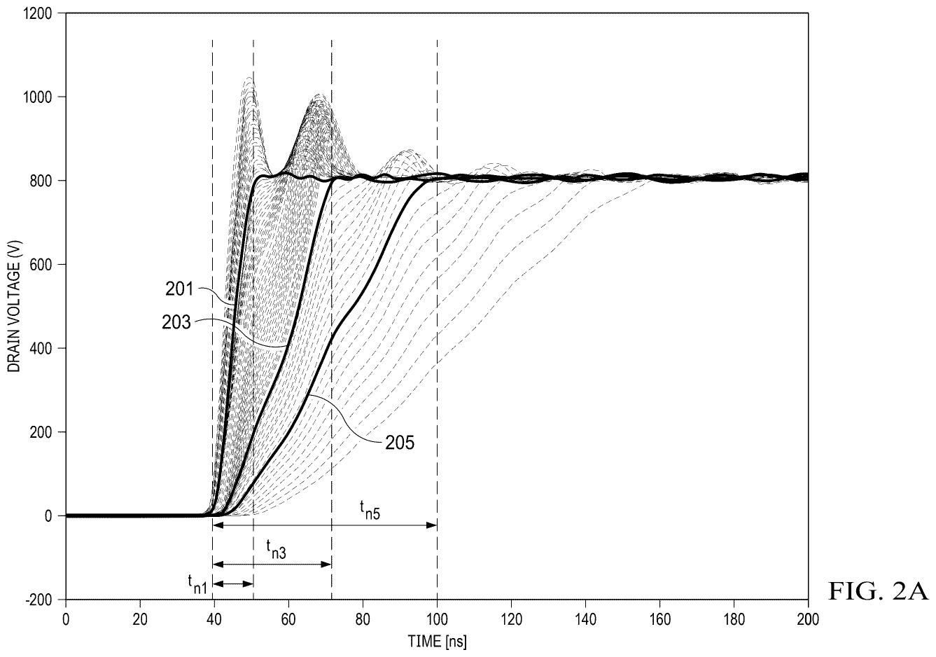

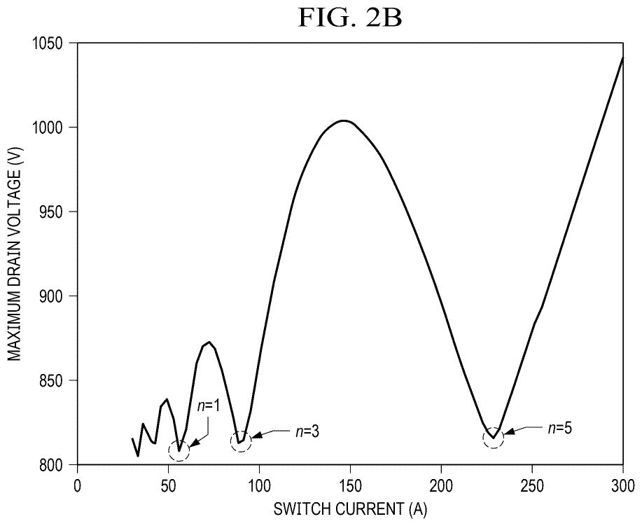

High-side transistor 131 and low-side transistor 141 may be coupled in series with each other between the DC voltage bus VBUS and the system ground GND. For example, high-side transistor 131 may be coupled between the DC voltage bus VBUS and a switching node SW. Specifically, high-side transistor may have a drain coupled to the DC voltage bus VBUS and a source coupled to the switching node SW. Further, low-side transistor 141 may be coupled between the switching node SW and the system ground GND. Specifically, low-side transistor may have a drain coupled to the switching node SW and a source coupled to the system ground GND. As shown in FIG. 2, high-side transistor 131 and low-side transistor 141 may in some embodiments be n-type metal-oxide-semiconductor field-effect transistors (n-type MOSFETs or NMOS transistors). In other embodiments, high-side transistor 131 and low-side transistor 141 may be implemented with integrated-gate bipolar transistors (IGBTs). Further, in some embodiments, high-side transistor 131 and low-side transistor 141 may be silicon carbide (SiC) transistors formed on respective silicon carbide semiconductor dies. In other embodiments, high-side transistor 131 and low-side transistor 141 may be formed with other semiconductor materials, such as silicon (Si), gallium nitride (GaN), or any other semiconductor material suitable for the high-voltage operation of switch system 100.

In some embodiments, switch system 100 may be part of an inverter system. For example, high-side transistor 131 and low-side transistor 141 may form one phase of a three-phase inverter, and the load 150 coupled to the switching node SW may be coil of one phase of a three-phase motor that is driven by the three-phase inverter.

Control circuit 120 may be configured to drive high-side transistor 131 and low-side transistor 141 on and off in an alternating fashion from each other. For example, when driving high-side transistor 131 in a high-side on-state, control circuit 120 may also drive low-side transistor 141 in a low-side off-state. Further, when driving high-side transistor 131 in a high-side off-state, control circuit 120 may also drive low-side transistor 141 in a low-side on-state. In some embodiments, control circuit 120 may drive high-side transistor 131 and low-side transistor 141 such that their respective on-states are non-overlapping to prevent high and uncontrolled shoot-through currents that may otherwise occur if high-side transistor 131 and low-side transistor 141 were both held in an on-state at the same time.

As shown in FIG. 1, DC power source 110, high-side transistor 131, and low-side transistor 141 may form a loop 111 that includes parasitic loop inductance (L_{PAR}) 155. The parasitic loop inductance 155 may represent the sum of the parasitic inductances within the loop 111 formed by high-side transistor 131, low-side transistor 141, and DC power source 110. For example, the parasitic loop inductance 155 may include any parasitic inductances along the electrical line forming the DC voltage bus VBUS coupling a first terminal of DC power source 110 to the drain of high-side transistor 131, along the electrical line forming the system ground GND coupling a second terminal of DC power source 110 to the source of low-side transistor 141, and along the electrical line coupling the source of high-side transistor 131 to the drain of low-side transistor 141 at switching node SW. The parasitic loop inductance 155 may further include, for example, the inductance of any bond wire or bond ribbon connections used at the drain and/or source terminals of the physical semiconductor die packages encapsulating high-side transistor 131 and low-side transistor 141. Although FIG. 1 illustrates parasitic loop inductance 155 along the DC voltage bus VBUS between DC power source 110 and high-side transistor 131, it is understood that parasitic loop inductance 155 represents the cumulative parasitic inductance spread throughout the loop 111.

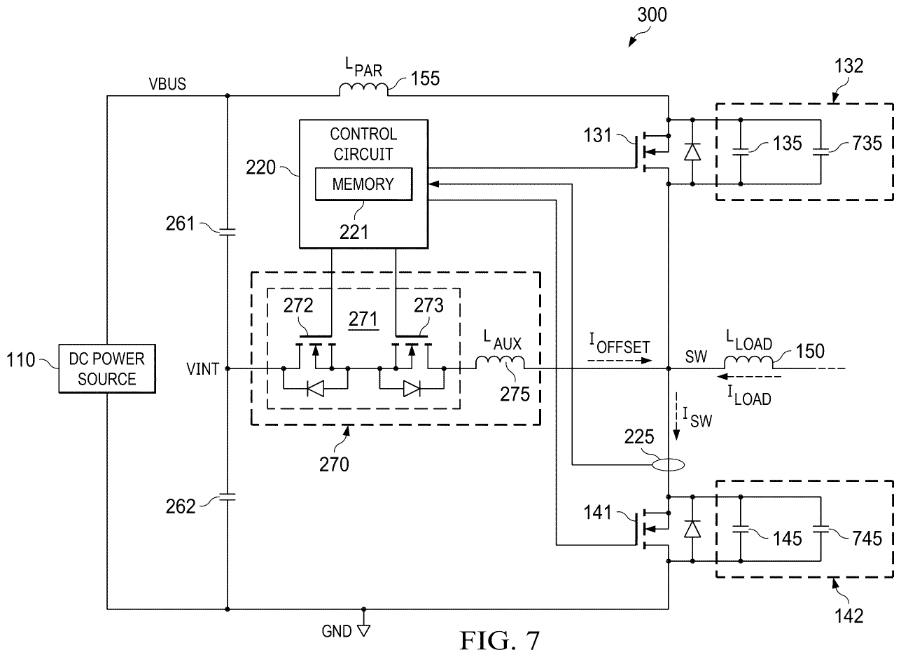

High-side transistor 131 and low-side transistor 141 may also contribute to a switch-node capacitance that includes high-side capacitance 132 from the drain to the source of high-side transistor 131, and a low-side capacitance 142 from the drain to the source of low-side transistor 141. As shown in FIG. 1, high-side capacitance 132 may include, for example, the parasitic drain-to-source capacitance 135 of high-side transistor 131. Further, low-side capacitance 142 may include, for example, the parasitic drain-to-source capacitance 145 of low-side transistor 141. And as described in further detail below with reference to FIG. 7, the switch-node capacitance including high-side capacitance 132 and low-side capacitance 142 may further include the capacitance of optional discrete capacitors coupled from the drain to the source of high-side transistor 131 and low-side transistor 141 respectively.

The parasitic loop inductance and the switch-node capacitance may have a resonant frequency as expressed by the following equation:

$$Resonant Frequency = \frac{1}{2 π \sqrt{{L}_{PAR} * {C}_{SW}}}$$

where L_{PAR} represents the parasitic loop inductance 155 and C_{SW} represents the switch-node capacitance. As described in further detail below, embodiments disclosed herein may utilize resonance of the parasitic loop inductance and the switch-node capacitance to provide for zero-overvoltage switching (ZOS) when low-side transistor 141 transitions from a low-side on-state to a low-side off-state. The zero-overvoltage switching (ZOS) may allow for a fast turn-off of low-side transistor 141 without incurring a large overvoltage at the drain of the low-side transistor 141.

Prior to the switching transition, a load current I_{LOAD} may flow from load 150 and through low-side transistor 141 to system ground GND. The switch current I_{SW} during this time may equal the load current I_{LOAD}. When low-side transistor 141 transitions from an on-state to an off-state, the inductive load may cause an overshoot at the drain of low-side transistor 141 (at the switching node SW) during the non-overlap time prior to high-side transistor 131 turning on.

Zero overvoltage switching (ZOS) may occur when the energy stored in the parasitic loop inductance 155 of loop 111 matches the energy required to commutate the switch current from low-side transistor 141 to high-side transistor 131. ZOS operating points may occur when the commutation time for a given switch current is equal to an n-half of the resonant period of the resonant circuit formed by the parasitic loop inductance (L_{PAR}) 155 and the switch-node capacitance C_{SW} (which depends on the high-side capacitance 132 and the low-side capacitance 142), where n is a positive odd whole number (for example, 1, 3, 5, 7, 9, or more). For example, a first ZOS operating point may occur when the commutation time for a given switch current is equal to one-half the resonant period of the resonant circuit formed by the parasitic loop inductance (L_{PAR}) 155 and the switch-node capacitance C_{SW}. As other examples, further ZOS operating points may occur when the commutation time for a given switch current is equal to three-halves or five-halves of the resonant period of the resonant circuit formed by the parasitic loop inductance (L_{PAR}) 155 and the switch-node capacitance C_{SW}. The switch current at which ZOS may occur can be described by the following ZOS operating-point equation:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents the high-side capacitance 132, C_{DSLS} represents the low-side capacitance 142, L_{PAR} represents the parasitic loop inductance 155 of loop 111, VBUS represents the voltage of the DC voltage bus relative to the system ground GND, and n is a positive odd whole number (for example, 1, 3, 5, 7, 9, or more).

FIG. 2A illustrates plot diagrams of the drain voltage of low-side transistor 141 in response to a switching transition. Specifically, FIG. 2A illustrates plot diagrams of the drain voltage of low-side transistor 141 in response to a transition from a low-side on-state to a low-side off-state for a plurality of switch currents. Plot 201 illustrates the drain voltage of low-side transistor 141 rising during commutation time tₙ₁ when the switch current is set according to n=1 in the above ZOS operating-point equation. Plot 203 illustrates the drain voltage of low-side transistor 141 rising during commutation time tₙ₃ when the switch current is set according to n=3. And plot 205 illustrates the drain voltage of low-side transistor 141 rising during commutation time tₙ₅ when the switch current is set according to n=5. As shown in FIG. 2A, the overshoot of the drain voltage above the VBUS value (800 V) is significantly reduced when the given switch current is set at a value where n=1, n=3, and n=5.

FIG. 2B illustrates a plot diagram of the maximum voltage incurred at the drain of the low-side transistor 141 during the switching transition as a function of switch current. As described above with reference to FIG. 2A, and as further shown in FIG. 2B, the maximum voltage incurred at the drain of low-side transistor 141 during the switching transition varies as a function of the commutated switch current. Specifically, the maximum voltage incurred at the drain of low-side transistor 141 during the switching transition may be lowest when the given switch current is set at a value where n=1, n=3, and n=5 in the above ZOS operating-point equation.

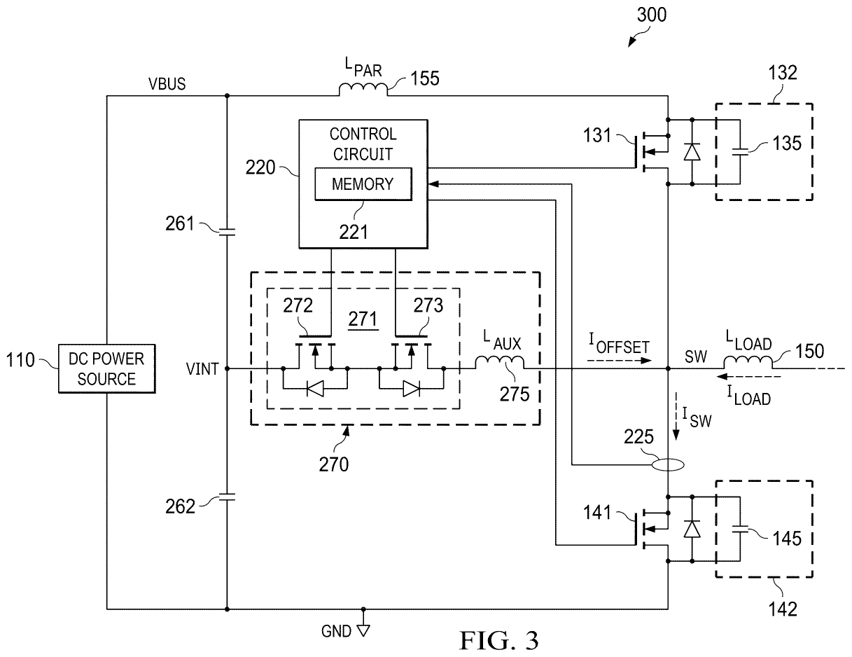

FIG. 3 illustrates a schematic diagram of switch system 300 in accordance with embodiments of the present disclosure. In some embodiments, switch system 300 may include DC power source 110, high-side transistor 131, low-side transistor 141, and load 150, which may be configured and operate in a similar manner as described above with reference to switch system 100 in FIG. 1. Accordingly, DC power source 110, high-side transistor 131, and low-side transistor 141 may form a loop that includes parasitic loop inductance (L_{PAR}) 155, as well as a switch-node capacitance C_{SW} (based on high-side capacitance 132 and low-side capacitance 142) in the same manner as described above with reference to FIG. 1.

As described above with reference to FIGS. 1, 2A, and 2B, embodiments disclosed herein may utilize resonance of the parasitic loop inductance and the switch-node capacitance to provide for zero-overvoltage switching (ZOS) when low-side transistor 141 transitions from a low-side on-state to a low-side off-state. Prior to the switching transition of low-side transistor 141 from a low-side on-state to a low-side off-state, a load current I_{LOAD} may flow from load 150 and through low-side transistor 141 to system ground GND. ZOS operating points may occur when the commutation time for a given switch current I_{SW} is equal to an n-half of the resonant period of the resonant circuit formed by the parasitic loop inductance (L_{PAR}) 155 and the switch-node capacitance C_{SW} (which depends on the high-side capacitance 132 and the low-side capacitance 142), where n is a positive odd whole number (for example, 1, 3, 5, 7, 9, or more). For example, a first ZOS operating point may occur when the commutation time for a given switch current is equal to one-half the resonant period of the resonant circuit formed by the parasitic loop inductance (L_{PAR}) 155 and the switch-node capacitance C_{SW}. As other examples, further ZOS operating points may occur when the commutation time for a given switch current is equal to three-halves or five-halves of the resonant period of the resonant circuit formed by the parasitic loop inductance (L_{PAR}) 155 and the switch-node capacitance C_{SW}. The switch current I_{SW} at which ZOS may occur can be described by the following ZOS operating-point equation:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents the high-side capacitance 132, C_{DSLS} represents the low-side capacitance 142, L_{PAR} represents the parasitic loop inductance 155 of loop 111, VBUS represents the voltage of the DC voltage bus relative to the system ground GND, and n is a positive odd whole number (for example, 1, 3, 5, 7, 9, or more).

Referring back to FIG. 3, switch system 300 may include control circuit 220 and auxiliary circuit 270. Control circuit 220 may be configured to control the switching on and off of high-side transistor 131 and low-side transistor 141 in a similar manner as described above for control circuit 120 in FIG. 1. In addition, control circuit 220 may be configured to control auxiliary circuit 270 to provide an offset current I_{OFFSET}, for example, during the switching transition of low-side transistor 141 from a low-side on-state to a low-side off-state. As described in further detail below, the offset current I_{OFFSET} may be utilized to force the switch current I_{SW} during the switching transition to a ZOS operating point regardless of whether the load current I_{LOAD} aligns with a ZOS operating point. The benefits of ZOS switching may thus be realized across a large range of arbitrary load currents.

As shown in FIG. 3, switch system 300 may include capacitor 261 and capacitor 262 coupled in series between the DC voltage bus VBUS and the system ground GND. The intermediate node between capacitor 261 and capacitor 262 may thus provide an intermediate supply rail VINT.

Auxiliary circuit 270 may include switch 271 and auxiliary winding (L_{AUX}) 275 coupled in series between the intermediate supply rail VINT and the switching node SW. For example, switch 271 may be coupled between the intermediate supply rail VINT and auxiliary winding (L_{AUX}) 275 while auxiliary winding 275 is in turn coupled between switch 271 and the switching node SW. In some embodiments, switch 271 may include two transistors coupled back-to-back. For example, as shown in FIG. 3, some embodiments of switch 271 may include first transistor 272 and second transistor 273. In some embodiments, first transistor 272 and second transistor 273 may be NMOS transistors. First transistor 272 may have a drain coupled to VINT, a source coupled to the source of second transistor 273, and a gate coupled to be controlled by control circuit 220. Second transistor 273 may have a drain coupled to the switch node SW, a source coupled to the source of first transistor 272, and a gate coupled to be controlled by control circuit 220. The back-to-back configuration of first transistor 272 and second transistor 273 may prevent the body diode of any one of the two transistors from alone creating a conduction path through switch 271. Thus, the conduction of current through switch 271 may thus be controlled closely by control circuit 220.

In some embodiments, auxiliary circuit 270 may be configured to, during a switching transition of low-side transistor 141 from a low-side on-state to a low-side off-state, provide an offset current I_{OFFSET} to the low-side transistor 141 that, in combination with the load current I_{LOAD}, triggers a resonance of the parasitic loop inductance and the switch-node capacitance. Specifically, auxiliary circuit 270 may be configured to, during a switching transition of low-side transistor 141 from a low-side on-state to a low-side off-state, provide an offset current I_{OFFSET} to the low-side transistor 141 that, in combination with the I_{LOAD}, triggers a resonant transition based on a resonance of the parasitic loop inductance (L_{PAR}) 155 and the switch-node capacitance C_{SW}.

For example, prior to a switching transition of low-side transistor 141 from a low-side on-state to a low-side off-state, control circuit 220 may drive the switch 271 within auxiliary circuit 270 in an on-state. The current through auxiliary winding 275 may begin to rise, thus providing an offset current I_{OFFSET} at the switching node SW. The switch current I_{SW} during this time may equal the sum of the load current I_{LOAD} plus the offset current I_{OFFSET}. In some embodiments, control circuit 220 may control auxiliary circuit 270 such that the offset current I_{OFFSET} provided by auxiliary circuit 270 pushes the switch current I_{SW} at the switching transition to a ZOS operating point.

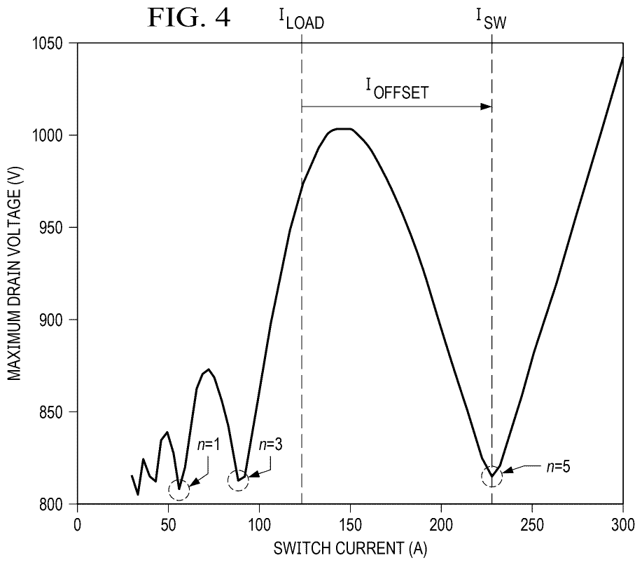

FIG. 4 illustrates a plot diagram of the maximum voltage incurred at the drain of the low-side transistor 141 during the switching transition as a function of switch current in accordance with embodiments of the present disclosure. As described above, the maximum voltage incurred at the drain of low-side transistor 141 during the switching transition varies as a function of the commutated switch current. Specifically, the maximum voltage incurred at the drain of low-side transistor 141 during the switching transition may be lowest when the switch current I_{SW} is at a value where n=1, n=3, and n=5 in the ZOS operating-point equation described above.

As shown in FIG. 4, the load current I_{LOAD} may be for example 125 A. The offset current I_{OFFSET} may thus be set at roughly 100 A to push the switch current I_{SW} to a ZOS operating point (for example, where n=5) of switch system 100. Although FIG. 4 illustrates one example of the offset current I_{OFFSET} pushing an example load current I_{LOAD} to a ZOS operating point of switch system 300, control circuit 220 may control auxiliary circuit 270 such that the offset current I_{OFFSET} supplements any arbitrary load current I_{LOAD} to push the switch current I_{SW} to a ZOS operating point for switch system 300. For example, the offset current I_{OFFSET} may be controlled to be any non-zero current that forces the switch current I_{SW} through low-side transistor 141 during the switching transition of the low-side transistor 141 to trigger an n-half resonant transition where n is a positive odd whole number (for example, 1, 3, 5, 7, 9, or more). Specifically, the offset current may be controlled to be any non-zero current that forces the switch current I_{SW} through low-side transistor 141 during the switching transition of the low-side transistor 141 to approximately equal:

$$\frac{VBUS \sqrt{\frac{{( {C}_{DSHS} + {C}_{DSLS} )}^{2}}{{C}_{DSHS} {C}_{DSLS} {L}_{PAR}}}}{n π}$$

where C_{DSHS} represents the high-side capacitance 132, C_{DSLS} represents the low-side capacitance 142, L_{PAR} represents the parasitic loop inductance 155, VBUS represents the voltage of the DC voltage bus relative to the system ground GND, and n is a positive odd whole number (for example, 1, 3, 5, 7, 9, or more).

Referring back to FIG. 3, switch system 300 may include current sensor 225. Current sensor 225 may be configured to detect the switch current I_{SW} through low-side transistor 141. In some embodiments, current sensor 225 may be implemented for example with a sense-FET that may be integrated within low-side transistor 141 and may produce a sense current proportional to the switch current I_{SW} through low-side transistor 141. Current sensor 225 may also be implemented by any other means suitable to detect the switch current I_{SW} through low-side transistor 141.

Control circuit 220 may receive a sense signal (such as a sense current or a sense voltage corresponding to the switch current I_{SW}) from current sensor 225. Control circuit 220 may thus be configured to monitor the switch current I_{SW} through the low-side transistor 141 prior to the switching transition of low-side transistor 141 from a low-side on-state to a low-side off-state. Control circuit 220 may in turn drive the auxiliary circuit to provide the offset current I_{OFFSET} based on the monitored switch current I_{SW}. For example, prior to a switching transition, control circuit 220 may detect the switch current I_{SW}, which may initially be equal to the load current I_{LOAD}. Based on the detected switch current I_{SW}, control circuit 220 may drive auxiliary circuit 270 to provide an offset current I_{OFFSET}. The offset current I_{OFFSET} may increase at a rate based on the voltage difference across auxiliary winding 275 divided by the inductance of auxiliary winding 275. Control circuit 220 may thus control the amount of offset current I_{OFFSET} provided at the switching transition of low-side transistor 141 by controlling the amount of time before the switching transition of low-side transistor 141 that control circuit 220 enables auxiliary circuit 270. And as described above, control circuit 220 may determine the target offset current I_{OFFSET} based on a difference between the initial detected switch current I_{SW} (prior to the application of the offset current I_{OFFSET}) and a selected ZOS operating point (for example the next higher ZOS operating point) of switch system 300.

As shown in FIG. 3, control circuit 220 may include memory 221. In some embodiments, memory 221 may be programmable, and may be used to store the ZOS operating points of switch system 300. For example, as described by the ZOS operating-point equation above, the ZOS operating points of switch system 300 may depend on the parasitic loop inductance (L_{PAR}) 155 and the switch-node capacitance C_{SW} which may be based at least in part on the parasitic drain-to-source capacitance 135 of high-side transistor 131 and the parasitic drain-to-source capacitance 145 of low-side transistor 141. These parameters may be determined for example after assembly of switch system 300, or estimated for example before assembly based on the design of switch system 300. Thus, ZOS operating points based on these determined or estimated parameters may be programmed into memory 221 either prior to, or after, the assembly of switch system 300. Further, the voltage value of the intermediate voltage rail VINT and the inductance value of auxiliary winding 275 may likewise be programmed and stored in memory 221. These parameters may allow control circuit 220 to accurately control the offset current I_{OFFSET} at the switching transition of low-side transistor 141 from the low-side on-state to the low-side off-state by controlling the timing of auxiliary circuit 270 relative to the switching transition.

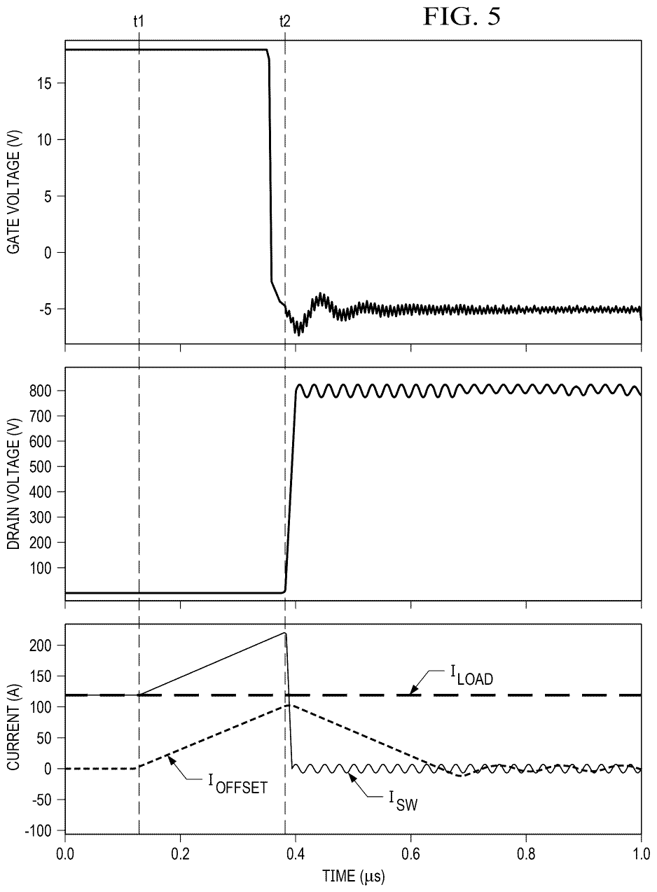

FIG. 5 illustrates plot diagrams of waveforms within switch system 300 in accordance with embodiments of the present disclosure. Specifically, FIG. 5 illustrates plot diagrams of waveforms within switch system 300 during a switching transition of low-side transistor 141 from a low-side on-state to a low-side off-state.

As shown in FIG. 5, the load current I_{LOAD} may be approximately 125 A during the switching transition. Although load 150 may be inductive, load 150 may have a high inductance value such that the I_{LOAD} has only a negligible change during the time scale of the switching transition shown in FIG. 5. As described above with reference to FIG. 4, switch system 300 may in some embodiments have a ZOS operating point at 225 A where n=5 in the ZOS operating-point equation. Accordingly, control circuit 220 may turn on switch 271 of auxiliary circuit 270 at time t1 to generate the offset current I_{OFFSET}. As described above, the offset current I_{OFFSET} may rise as a function of the voltage across auxiliary winding 275 (roughly VINT minus the voltage at switching node SW) divided by the inductance of auxiliary winding 275. As the time line approaches time t2, control circuit 220 may drive the gate voltage of low-side transistor 141 low to transition low-side transistor 141 from a low-side on-state to a low-side off-state. At time t2, the offset current I_{OFFSET} may be at 100 A, thereby pushing the switch current I_{SW} to 225 A (the sum of I_{OFFSET} and I_{LOAD}), which as described above with reference to FIG. 4, may align with the ZOS operating point of switch system 300 for n=5. Accordingly, a resonant transition may be initiated at time t2, significantly reducing the voltage overshoot (over the VBUS voltage of 800V) at the drain of low-side transistor 141 that would otherwise occur if the switch current I_{SW} was not aligned with a ZOS operating point at time t2.

As shown in FIG. 5, the gate voltage of low-side transistor 141 may be driven from high to low at high speed. For example, in some embodiments, control circuit 220 may drive the gate voltage of low-side transistor such that low-side transistor 141 transitions from the low-side on-state to the low-side off-state in less than one resonant period of the parasitic loop inductance and the switch-node capacitance. Embodiments of a low-side driver configured to provide a fast turn-off of low-side transistor 141 are described below.

As described above with reference to FIGS. 3-5, auxiliary circuit 270 may be utilized to provide an offset current I_{OFFSET} to push the switch current I_{SW} to a ZOS operating point at switching transition of low-side transistor 141 from a low-side on-state to a low-side off-state. Auxiliary circuit 270 may also be controlled by control circuit 220 to prevent the switch current I_{SW} from being negative (flowing from source to drain) at the switching transition of low-side transistor 141 from the low-side on-state to the low-side off-state. For example, if the switch current I_{SW} is negative just prior to the switching transition, control circuit 220 may engage auxiliary circuit 270 to provide an offset current I_{OFFSET} that, when combined with the load current I_{LOAD}, forces the total switch current I_{SW} positive (flowing from drain to source) at the switching transition. Control circuit 220 and auxiliary circuit 270 may thus prevent losses associated with transitioning low-side transistor 141 from a low-side on-state to a low-side off-state when the switch current I_{SW} to be commutated is negative.

As shown in FIG. 4, the maximum drain voltage incurred during the switching transition of low-side transistor 141 a low-side on-state to a low-side off-state may be low for small positive switch currents (for example, below 40 A). Accordingly, control circuit 220 may be configured to selectively engage auxiliary circuit 270 to provide an offset current I_{OFFSET} at the switching transition depending on the switch current I_{SW}. For example, if the switch current I_{SW} is negative prior to the switching transition, control circuit 220 may engage auxiliary circuit 270 to provide an offset current I_{OFFSET} that forces the total switch current I_{SW} to be positive (for example, 10 A) at the switching transition, thereby avoiding drawbacks of switching a negative current. If the switch current I_{SW} is positive, but below a threshold switch current (for example, 40 A), control circuit 220 may control auxiliary circuit 270 to provide no offset current, thereby allowing the switching transition to occur at the positive current below the threshold switch current. Further, if the switch current is above the threshold switch current (for example, 40 A), control circuit 220 may engage auxiliary circuit 270 to provide an offset current I_{OFFSET} that pushes the switch current I_{SW} at the switching transition to a next higher ZOS operating point as described above with reference to FIGS. 3-5.

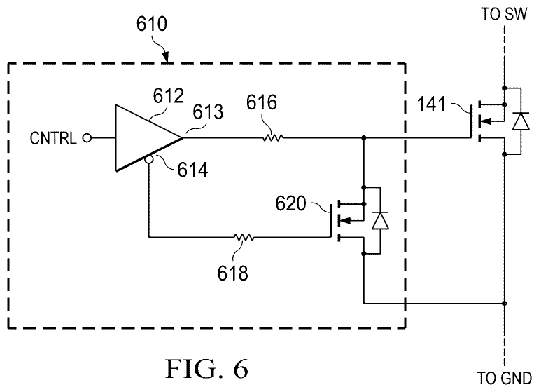

FIG. 6 illustrates a schematic diagram of low-side driver 610 in accordance with embodiments of the present disclosure. As shown in FIG. 6, low-side driver 610 may be configured to drive the gate of low-side transistor 141. In some embodiments, low-side driver 610 may be incorporated as part of control circuit 220. In other embodiments, low-side driver 610 may be implemented separately from control circuit 220, and may drive the gate of low-side transistor 141 according to a control signal CNTRL from control circuit 220. Low-side driver 610 may include a drive circuit 612, gate resistor 616, resistor 618, and pull-down transistor 620. Pull-down transistor 620 may be, for example, an NMOS transistor.

As shown in FIG. 6, drive circuit 612 may have a first output 613 and a second output 614. The first output 613 together with gate resistor 616 may control the rise of the gate voltage of low-side transistor 141 when low-side driver 610 transitions low-side transistor 141 from a low-side off-state to a low-side on-state. For example, gate resistor 616 may be coupled between the first output 613 of drive circuit 612 and the gate of low-side transistor 141. In response to a logic-high control signal CNTRL, drive circuit 612 may output a high voltage (for example, 18 V) at its first output 613 to turn on low-side transistor 141. The gate voltage may accordingly rise with a slew rate depending on the RC time constant of gate resistor 616 and the gate capacitance of low-side transistor 141. In some embodiments, the resistance of gate resistor 616 may be selected to slow the turn-on transition of low-side transistor 141. When first output 613 is high to turn on low-side transistor 141, the second output 614 may be low to disable pull-down transistor 620.

The second output 614 together with pull-down transistor 620 may control the fall of the gate voltage of low-side transistor 141 when low-side driver 610 transitions low-side transistor 141 from a low-side on-state to a low-side off-state. For example, pull-down transistor 620 may have a gate driven by the second output 614 of drive circuit 612 (via resistor 618), a drain coupled to the gate of low-side transistor 141, and a source coupled to the source of low-side transistor 141. In response to a logic-low control signal CNTRL, drive circuit 612 may output a low voltage at first output 613 and may output a high voltage at second output 614. The high voltage at the second output 614 may be, for example, 18 V or any other voltage suitable to turn on pull-down transistor 620. Pull-down transistor 620 may in turn discharge the gate capacitance of low-side transistor 141, driving the gate voltage low, and thereby turning off low-side transistor 141.

By utilizing pull-down transistor 620 to turn off low-side transistor 141, low-side driver 610 may bypass gate resistor 616, and thereby turn off low-side transistor 141 at a much faster turn-off speed relative to the turn-on speed that may be controlled by gate resistor 616. For example, in some embodiments, low-side driver 610 may be configured to transition low-side transistor 141 from an on-state to an off-state in less than one resonant period of the parasitic loop inductance L_{PAR} and the switch-node capacitance C_{SW} of switch system 300.

FIG. 7 illustrates a schematic diagram of switch system 300 in accordance with embodiments of the present disclosure. Specifically, FIG. 7 illustrates an additional embodiment of switch system 300 shown in FIG. 3 where high-side capacitance 132 further includes a first discrete capacitor 735 in addition to the parasitic drain-to-source capacitance 135 of high-side transistor 131, and where low-side capacitance 142 further includes a second discrete capacitor 745 in addition to the parasitic drain-to-source capacitance 145 of low-side transistor 141.

As described above, the parasitic loop inductance and the switch-node capacitance may have a resonant frequency as expressed by the following equation:

$$Resonant Frequency = \frac{1}{2 π \sqrt{{L}_{PAR} * {C}_{SW}}}$$

where L_{PAR} represents the parasitic loop inductance 155 and C_{SW} represents the switch-node capacitance. By adding first discrete capacitor 735 to high-side capacitance 132, and adding second discrete capacitor 745 to low-side capacitance 142, the switch-node capacitance C_{SW} may be increased. As a result, the resonant frequency of the parasitic loop inductance and the switch-node capacitance may be decreased. Accordingly, the resonant transition that occurs when operating at a ZOS operating point may be slowed. In some embodiments of switch system 300, a slower transition of the drain voltage of low-side transistor 141 may be desirable, for example to reduce the switching noise generated by switch system 300.

The embodiments of switch system 300 described herein may provide multiple advantages. By providing an offset current I_{OFFSET} during the transition of low-side transistor 141, the benefits of zero-overvoltage switching (ZOS) may be realized across a wide range of load currents that switch system 300 may be required to switch in practical applications, such as in 3-phase inverters used to drive electric motors. By reducing or eliminating the overvoltage that would otherwise be incurred at the drain of low-side transistor 141 during a turn-off transition, low-side transistor 141 may be safely implemented with a transistor that has a lower maximum voltage rating and thus a lower cost. Further, utilizing zero-overvoltage switching may reduce or eliminate the overvoltage without the switching loss that is incurred by other techniques that use gate resistance to slow the turn-off transition to prevent overshoot. Moreover, because zero-overvoltage switching utilizes the resonance of the parasitic loop inductance (L_{PAR}) 155 with the switch-node capacitance C_{SW} (based on high-side capacitance 132 and low-side capacitance 142), the zero-overvoltage switching described herein may be implemented without large snubber capacitors coupled to the switching node. For example, in some embodiments such as those described above with reference to FIG. 3, the zero over-voltage switching may simply utilize the parasitic capacitances of high-side transistor 131 and low-side transistor 141. In other embodiments, such as described above with reference to FIG. 5, additional discrete capacitors may be utilized to slow the resonant transition at the turn-off of low-side transistor 141. Such discrete capacitors may however be one or more orders of magnitude smaller, and thus less expensive, than the snubber capacitors utilized in traditional architectures such as auxiliary resonant commutated pole (ARCP) topologies.

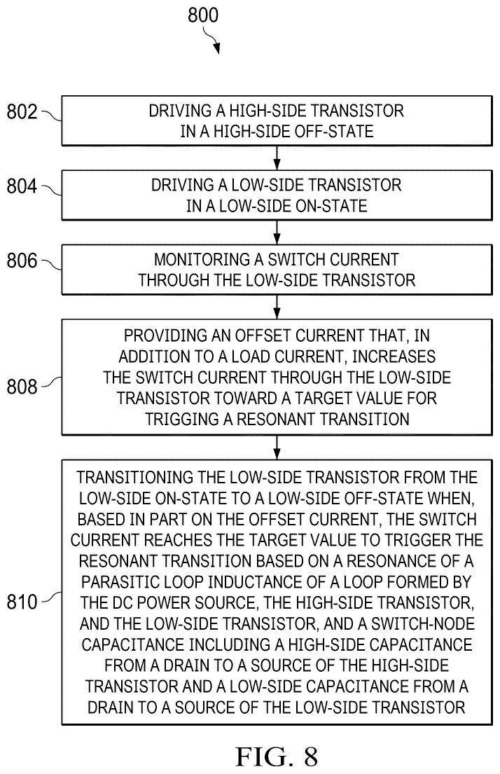

FIG. 8 illustrates an example method 800 of operating a switch system in accordance with embodiments of the present disclosure. Method 800 may be performed by any suitable mechanism, such as control circuit 220 and/or switch system 300, and/or any suitable combination of the components included therein. Method 800 may be performed with fewer or more steps than shown in FIG. 8. Moreover, steps of method 800 may be omitted, repeated, performed in parallel, performed in a different order than shown in FIG. 8, or performed recursively. One or more steps of method 800, although shown in an order, may be performed at the same time or in a re-ordered manner.

Step 802 may include driving a high-side transistor in a high-side off-state. The high-side transistor may be coupled between a switching node and a DC voltage bus powered by a DC power source. For example, as described above with reference to FIG. 3, high-side transistor 131 may be coupled between the switching node SW and the DC voltage bus VBUS that is power by DC power source 110. Further, as also described above with reference to FIG. 3, prior to and during the switching transition of the low-side transistor 141 from an low-side on-state to a low-side off-state, high-side transistor 131 may be driven in a high-side off state by control circuit 220.

Step 804 may include driving a low-side transistor in a low-side on-state. The low-side transistor coupled between the switching node and a system ground. For example, as described above with reference to FIG. 3, low-side transistor 141 may be coupled between the switching node SW and a system ground GND. Further, as also described above with reference to FIG. 3, low-side transistor 141 may be driven by control circuit 220 in a low-side on-state prior to the switching transition to a low-side off-state.

Step 806 may include monitoring the switch current through the low-side transistor. For example, as described above with reference to FIG. 3, control circuit 220 may receive a sense signal from current sensor 225, and may thus monitor the switch current I_{SW} through the low-side transistor 141 prior to the switching transition of low-side transistor 141 from a low-side on-state to a low-side off-state.

Step 808 may include providing an offset current that, in addition to a load current, increases a switch current through the low-side transistor toward a target value for trigging a resonant transition. In some embodiments, the offset current may be generated based on a value of the switch current relative to the target value. For example, as described above with reference to FIGS. 3 and 4, control circuit 220 may drive the auxiliary circuit to provide the offset current I_{OFFSET} based on the monitored switch current I_{SW}. Prior to a switching transition, control circuit 220 may monitor the switch current I_{SW}, which may initially be equal to the load current I_{LOAD}. Based on the detected switch current I_{SW}, control circuit 220 may control the amount of offset current I_{OFFSET} provided by auxiliary circuit 270 at the switching transition of low-side transistor 141. For example, control circuit 220 may determine the offset current I_{OFFSET} based on a difference between the initial detected switch current I_{SW} (prior to the application of the offset current I_{OFFSET}) and a target switch current at a ZOS operating point (for example the next higher ZOS operating point) of switch system 300.

Step 810 may include transitioning the low-side transistor from the low-side on-state to a low-side off-state when, based in part on the offset current, the switch current reaches the target value to trigger the resonant transition based on a resonance of a parasitic loop inductance of a loop formed by the DC power supply, the high-side transistor, and the low-side transistor, and a switch-node capacitance including a high-side capacitance from a drain to a source of the high-side transistor and a low-side capacitance from a drain to a source of the low-side transistor. For example, as described above with reference to FIG. 3 and FIG. 5, control circuit 220 may transition low-side transistor 141 from a low-side on-state to a low-side off state when the switch current I_{SW} (which equals the sum of the offset current I_{OFFSET} and the load current I_{LOAD}) reaches a target current value corresponding to a ZOS operating point of switch system 300. In the example illustrated in FIG. 5, the offset current I_{OFFSET} may be at 100 A at time t2, pushing the switch current I_{SW} to 225 A (the sum of I_{OFFSET} and I_{LOAD}), which as described above with reference to FIG. 4, may align with the ZOS operating point of switch system 300 for n=5. Accordingly, a resonant transition may be initiated based on a resonance of the switch-node capacitance C_{SW} and the parasitic loop inductance L_{PAR} of a loop formed by the DC power source 110, the high-side transistor 131, and the low-side transistor 141.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A switch system comprising:
a high-side transistor coupled between a DC voltage bus and a switching node;
a low-side transistor coupled between the switching node and a system ground;
a switch-node capacitance including a high-side capacitance from a drain to a source of the high-side transistor and a low-side capacitance from a drain to a source of the low-side transistor;
a DC power source coupled between the DC voltage bus and the system ground, wherein the DC power source, the high-side transistor, and the low-side transistor form a loop with a parasitic loop inductance;
a control circuit configured to drive the high-side transistor and the low-side transistor on and off in an alternating fashion from each other; and
an auxiliary circuit configured to, during a switching transition of the low-side transistor from a low-side on-state to a low-side off-state, provide an offset current to the low-side transistor that, in combination with a load current, triggers a resonance of the parasitic loop inductance and the switch-node capacitance.

2. The switch system of claim 1, wherein the offset current is a non-zero current that forces a switch current through the low-side transistor during the switching transition of the low-side transistor to trigger an n-half resonant transition wherein n is a positive odd whole number.

3. The switch system of claim 2, wherein n is one of 3 or 5 or more.

4. The switch system of claim 1, wherein the offset current is a non-zero current that forces a switch current through the low-side transistor during the switching transition of the low-side transistor to approximately equal:
$$\frac{VBUS \sqrt{\frac{{( {C}_{DSHS} + {C}_{DSLS} )}^{2}}{{C}_{DSHS} {C}_{DSLS} {L}_{PAR}}}}{n π}$$
where C_{DSHS} represents the high-side capacitance, C_{DSLS} represents the low-side capacitance, L_{PAR} represents the parasitic loop inductance, VBUS represents a voltage of the DC voltage bus relative to the system ground, and n is a positive odd whole number.

5. The switch system of claim 1, wherein:
the high-side capacitance includes a parasitic drain-to-source capacitance of the high-side transistor; and
the low-side capacitance includes a parasitic drain-to-source capacitance of the low-side transistor.

6. The switch system of claim 5, wherein:
the high-side capacitance further includes a first discrete capacitor; and
the low-side capacitance further includes a second discrete capacitor.

7. The switch system of claim 1, wherein the control circuit is configured to:
monitor a switch current through the low-side transistor prior to the switching transition; and
drive the auxiliary circuit to provide the offset current based on the switch current.

8. The switch system of claim 1, wherein the control circuit includes a low-side driver configured to transition the low-side transistor from an on-state to an off-state in less than one resonant period of the parasitic loop inductance and the switch-node capacitance.

9. The switch system of claim 8, wherein the control circuit includes a low-side driver including:
a drive circuit having a first output and a second output;
a gate resistance coupled between the first output of the drive circuit and a gate of the low-side transistor; and
a pull-down transistor having a gate driven by the second output of the drive circuit, a drain coupled to the gate of the low-side transistor, and a source coupled to a source of the low-side transistor.

10. The switch system of claim 1, wherein the high-side transistor and the low-side transistor are silicon carbide transistors.

11. The switch system of claim 1, wherein the high-side transistor and the low-side transistor are NMOS transistors.

12. A switch system comprising:
a high-side transistor coupled between a DC voltage bus and a switching node;
a low-side transistor coupled between the switching node and a system ground;
a switch-node capacitance including a high-side capacitance from a drain to a source of the high-side transistor and a low-side capacitance from a drain to a source of the low-side transistor;
a DC power source coupled between the DC voltage bus and the system ground, wherein the DC power source, the high-side transistor, and the low-side transistor form a loop with a parasitic loop inductance;
a control circuit configured to drive the high-side transistor and the low-side transistor on and off in an alternating fashion from each other; and
an auxiliary circuit configured to, during a switching transition of the low-side transistor from a low-side on-state to a low-side off-state, provide an offset current to the low-side transistor that, in combination with a load current, triggers a resonant transition based on a resonance of the parasitic loop inductance and the switch-node capacitance.

13. The switch system of claim 12, wherein the offset current is a non-zero current that forces a switch current through the low-side transistor during the switching transition of the low-side transistor to approximately equal:
$$\frac{VBUS \sqrt{\frac{{( {C}_{DSHS} + {C}_{DSLS} )}^{2}}{{C}_{DSHS} {C}_{DSLS} {L}_{PAR}}}}{n π}$$
where C_{DSHS} represents the high-side capacitance, C_{DSLS} represents the low-side capacitance, L_{PAR} represents the parasitic loop inductance, VBUS represents a voltage of the DC voltage bus relative to the system ground, and n is a positive odd whole number.

14. The switch system of claim 12, wherein the control circuit is configured to:
monitor a switch current through the low-side transistor prior to the switching transition; and
drive the auxiliary circuit to provide the offset current based on the switch current.

15. A method of operating a switch system comprising:
driving a high-side transistor in a high-side off-state, the high-side transistor coupled between a switching node and a DC voltage bus powered by a DC power source;
driving a low-side transistor in a low-side on-state, the low-side transistor coupled between the switching node and a system ground;
providing an offset current that, in addition to a load current, increases a switch current through the low-side transistor toward a target value for trigging a resonant transition; and
transitioning the low-side transistor from the low-side on-state to a low-side off-state when, based in part on the offset current, the switch current reaches the target value to trigger the resonant transition based on a resonance of a parasitic loop inductance of a loop formed by the DC power source, the high-side transistor, and the low-side transistor, and a switch-node capacitance including a high-side capacitance from a drain to a source of the high-side transistor and a low-side capacitance from a drain to a source of the low-side transistor.

16. The method of claim 15, wherein the resonant transition is an n-half resonant transition wherein n is a positive odd whole number.

17. The method of claim 15, wherein the offset current is a non-zero current that forces the switch current through the low-side transistor during an on-to-off transition of the low-side transistor to approximately equal:
$$\frac{VBUS \sqrt{\frac{{( {C}_{DSHS} + {C}_{DSLS} )}^{2}}{{C}_{DSHS} {C}_{DSLS} {L}_{PAR}}}}{n π}$$
where C_{DSHS} represents the high-side capacitance from a drain to source of the high-side transistor, C_{DSLS} represents the low-side capacitance from a drain to a source of the low-side transistor, L_{PAR} represents the parasitic loop inductance, VBUS represents a voltage of the DC voltage bus relative to the system ground, and n is a positive odd whole number.

18. The method of claim 15, further comprising:
monitoring the switch current through the low-side transistor; and
generating the offset current based on a value of the switch current relative to the target value.

19. The method of claim 15, wherein the switch-node capacitance includes a parasitic drain-to-source capacitance of the high-side transistor and a parasitic drain-to-source capacitance of the low-side transistor.

20. The method of claim 19, wherein the switch-node capacitance further includes a first discrete capacitor coupled from a drain to a source of the high-side transistor and a second discrete capacitor coupled from a drain to a source of the low-side transistor.
